(19) United States
(12) Patent Application Publication
(10) Pub. No.: US 2026/0342314 A1
(43) Pub. Date: Oct. 29, 2026

(54) EXCITONIC DEVICES FOR ON-CHIP DATA COMMUNICATION

(71) Applicant: The Regents of The University of Michigan, Ann Arbor, MI (US)

(72) Inventors: Kanak DATTA, Ann Arbor, MI (US); Zidong LI, Ann Arbor, MI (US); Parag DEOTARE, Ann Arbor, MI (US)

(73) Assignee: The Regents of The University of Michigan, Ann Arbor, MI (US)

(21) Appl. No.: 19/101,613

(22) PCT Filed: Aug. 16, 2023
(86) PCT No.: PCT/US2023/030319

§ 371 Date: Feb. 6, 2025

Related U.S. Application Data
(60) Provisional application No. 63/398,300, filed on Aug. 16, 2022.

(51) Int. Cl. H03H 9/42; H03H 9/02

(52) U.S. Cl. CPC H03H 9/42; H03H 9/02559

(57) ABSTRACT

Drift-diffusion dynamics is investigated in a one-dimensional (1D) exciton guide at room temperature. Spatial engineering of the exciton energy in a WSe₂ monolayer is achieved using local strain to confine as well as direct exciton transport. An unexpected and massive deviation from the Einstein relation is observed and correlated with the exciton capture by defects. Experiments at elevated exciton densities reveal that the exciton drift velocity monotonically increases with exciton density, unlike exciton mobility, due to contributions from the non-equilibrium many-body effects.

### CROSS-REFERENCE TO RELATED APPLICATIONS

This claims the benefit of U.S. Provisional Application No. 63/398,300, filed on Aug. 16, 2022. The entire disclosure of this application is incorporated herein by reference.

### GOVERNMENT CLAUSE

This invention was made with government support under W911NF-21-1-0207 awarded by the U.S. Army Research Office. The government has certain rights in the invention.

### FIELD

The present disclosure relates to an interconnect system for use on a microchip.

### BACKGROUND

Coulombically bound electron-hole pairs (commonly known as excitons) provide an effective platform to transport energy at the nanoscale. Coupled with small dimension and seamless transition with photons, excitons have the potential to serve various applications in energy conversion, light emission, chemical sensing, and information processing and communication. With the recent emergence of two-dimensional semiconductors such as transition metal dichalcogenides (TMDs) that support excitons with high diffusivity and binding energy (>100 meV) the feasibility of room-temperature excitonic devices is no longer questionable8. However, the spatial manipulation of exciton flux that is critical to control energy flow at the nanoscale remains a challenge, especially at room temperature. Unlike charged particles that drift under an externally applied electric field, the directed transport of charge-neutral exciton flux is achieved by the spatial tuning of exciton potential by external stimuli such as mechanical strain or electric field. Travelling surface acoustic waves (SAWs) can dynamically utilize both effects to achieve long-range transport.

This disclosure studies the spatiotemporal control of exciton flux in a monolayer tungsten diselenide (WSe₂) system at room temperature. High-frequency (resonance frequency, ~745 MHz) Rayleigh-type SAWs are generated in a piezoelectric 1280 Y-cut lithium niobate (LiNbO3) substrate using interdigitated electrodes (IDTs). Mechanically exfoliated monolayer WSe₂ encapsulated in hexagonal boron nitride (hBN) was transferred on the SAW delay line using a dry transfer technique. Using phase-synchronized spatiotemporal measurements and utilizing photogenerated free carriers to screen the in-plane electric field, directed exciton transport is reported under type-I bandgap modulation and charge transport is reported in type-II modulation. Based on experiments, a drift velocity of 600 m s-1 is extracted for a strain amplitude of ~0.086% and the neutral exciton mobility is estimated to be about 900 cm² (eVs)-1. In addition, precise manipulation over the exciton transport is demonstrated by controlling the phase delay between radio-frequency (RF) excitation and photoexcitation. This disclosure also provides important insights into the weak coupling regime between the dynamic strain wave and room-temperature excitons in a two-dimensional semiconductor system, leading to a potential pathway for long-range exciton transport at room temperature.

This section provides background information related to the present disclosure which is not necessarily prior art.

### SUMMARY

This section provides a general summary of the disclosure, and is not a comprehensive disclosure of its full scope or all of its features.

An innovative technique is presented for transporting energy within a microchip. The method includes: providing an exciton guide that interconnects two circuit components on the microchip, the exciton guide having a ridge formed on a surface thereof; disposing an excitonic material on the exciton guide; generating an exciton along the ridge of the exciton guide; and creating a mechanical strain along the ridge of the exciton guide, thereby transporting the exciton along the ridge of the exciton guide.

In one aspect, an interconnect system is implemented on a microchip. The interconnect system includes: an exciton guide having a ridge formed on a surface thereof; excitonic material disposed on the surface of the exciton guide; an exciton source configured to create an exciton along the ridge of the exciton guide; and a transducer interfaced with the exciton guide and operates to control transport of excitons along the ridge of the exciton guide using surface acoustic waves.

In one embodiment, the exciton guide is a piezoelectric material and the transducer is an AC voltage source configured to apply an AC voltage to the piezoelectric material.

In another aspect, an interconnect system is comprised of: an exciton guide having a ridge formed on a surface thereof, where the ridge has a unidirectional grade from one end to the other end; excitonic material disposed on the surface of the exciton guide; and an exciton source configured to create an exciton along the ridge of the exciton guide, such that the exciton moves along the ridge.

In either embodiment, the excitonic source may be implemented by a light source configured to project light onto the excitonic material. Alternatively, the excitonic source may be implemented by an electrical source configured to inject carriers onto the exciton guide.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1A is a diagram depicting an example interconnect system for use in a microchip.

FIG. 1B is a brightfield optical image of hBN-encapsulated monolayer WSe₂ transferred onto a LiNbO3 substrate patterned with interdigitated electrodes.

FIG. 1C is an integrated PL intensity map of monolayer area represented by the square in FIG. 1B.

FIG. 1D is a graph showing PL intensity modulation under increased RF power at various optical excitation densities, where the monolayer PL emission decreases with an increase in the RF power and the net PL quenching, however, reduces with increasing optical power density due to screening from the optically generated free carriers.

FIGS. 2A and 2B are spatiotemporal exciton density profiles (log scale) from phase-synchronized TCSPC measurement for RF excitation inputs of −60 dBm and 13 dBm, respectively.

FIGS. 2C and 2D are spatiotemporal maps of exciton density (normalized for each time instance along space) for RF input powers of −60 dBm and 13 dBm, respectively, at an optical fluence of 1.2 μJ cm, where spatial shift in exciton density can be observed under RF excitation.

FIGS. 2E and 2F are normalized exciton density profiles at different time instances as a function of space along with the Gaussian fit under RF input powers of −60 dBm and 13 dBm, respectively. At the minimum RF input power (−60 dBm), the exciton density symmetrically broadens in space due to exciton diffusion in the monolayer. At a high RF input power, an asymmetric spatial shift in the exciton density in the direction of acoustic wave propagation is observed with the observed shift increasing with time. To improve the signal-to-noise ratio, the raw data were binned using a 100 ps window.

FIG. 3A is a graph showing the spatiotemporal evolution of the exciton density peak extracted using Gaussian fits (circles) and the approximate linear fit (solid lines) at various acoustic powers. The error bars represent the 95% confidence bound in the Gaussian fit.

FIG. 3B is a graph showing the effective shift in the position of the Gaussian peak extracted from the model introduced earlier that shows an increase in transport length as the RF input power increases. The maximum shift in the Gaussian peak increases with the applied RF input power, a clear signature of long-range energy transport under dynamic strain in the monolayer. The error bar for each data point represents the 95% confidence bound in the linear fit for the extraction of vavg using equation (1) below.

FIG. 3C is a graph showing the time derivative of the 13 dBm data in FIG. 3A. The instantaneous velocity of the exciton flux reaches 600 m s-1, but it is still lower than the acoustic wave velocity (3,979 m s-1). To improve the signal-to-noise ratio, the raw data were binned using a 100 ps window.

FIGS. 4A-4D are schematics of the photogenerated excitons at different SAW phases along with exciton potential: τ; τ+T/4; τ+T/2; and τ+37/4, respectively. The vertical line represents the position of the excitation pulse on the SAW wave. For τ, the excitons are generated at a position such that the energetically stable position lies in the opposite direction of SAW propagation. Therefore, immediately after photogeneration, the exciton density distribution shifts in the opposite direction of SAW propagation. However, as the excitons couple to the travelling strain field, a net drift in the direction of SAW was observed. For τ+T/4, excitons are generated at the positions of the lowest bandgap (position of the maximum tensile strain corresponding to the minimum exciton potential but the lowest energy gradient). Hence, the exciton density distribution does not undergo an immediate spatial shift after photogeneration. At τ+T/2, following photoexcitation, the energy gradient drives the exciton flux forward towards the stable position of the maximum tensile strain. Therefore, the generated density distribution moves immediately in the direction of SAW propagation. For τ+3T/4, the excitons are generated at the position of the maximum compressive strain, that is, the maximum bandgap, and hence results in no spatial shift immediately after photogeneration.

FIG. 4E is a graph showing the phase-synchronized evolution of the Gaussian peak position (circles) extracted by fitting the normalized exciton density measured using the TCSPC technique. The Gaussian peak position oscillates with the period of the SAW wave. A progressive delay in the Gaussian peak is also observed as the time delay is increased at an increment of T/4. Alongside the oscillations, a net drift in the Gaussian peak is observed in the direction of acoustic wave propagation.

FIG. 5 is a diagram depicting an alternative embodiment of an interconnect system for use in a microchip.

FIG. 6 is a diagram depicting another embodiment of an interconnect system for use in a microchip.

FIG. 7A is a topographic atomic force microscopy image of a WSe₂ sample on a tapered nanoridge. Strain generates a unidirectional gradient (red arrow) and confinement (green curve) in the exciton potential. Spatial changes of the exciton potential are estimated by spatially resolved photoluminescence (PL) measurements of the exciton energy shift along (x direction) and perpendicular (y direction) to the nanoridge. Shaded areas indicate the spatial region relevant for the 1D guide. By growing nanoridges with different heights, one can adjust the strain gradient from F=1.14 meV/μm to 5.59 meV/μm (2.03 meV/μm for this representative sample).

FIG. 7B is a time-integrated image of the PL on the nanoridge (contours shown as white dashed lines) with the strongest F. The yellow and white regions correspond to 10% and 50% of initial PL intensity in the 1D guide, whereas the blue contour lines show corresponding levels from an unstrained sample. The red region denotes the laser profile for 50% peak value.

FIG. 7C is a graph showing drift visibility over time for 1D guide and unstrained sample.

FIG. 8A is a schematic illustrating drift and diffusion contributions to exciton transport in a 1D guide.

FIG. 8B is a graph showing time-dependent peak position (red dashed line), centroid of distribution (red squares) and mean squared displacement (blue dots) of the exciton distribution.

FIG. 8C is a graph showing drift velocity v (red squares) and diffusivity D (blue dots), defined from time-derivatives of the respective data sets shown in (b) during the first 5 ns, for five samples with varying strain gradient F₁ₛ. An estimate for D based on the measured mobility μ and the Einstein relation (blue dash-dotted line) shows strong deviations compared to the measured D (blue dashed line).

FIGS. 8D-8F are spatiotemporal maps along the x-direction is reproduced by numerical solutions of drift-diffusion equations using the measured D and u values. The scans are normalized for each time and the excitation laser profile is shown by the white curve. Peak position and one standard-deviation of the distribution is represented by black dashed and solid lines, respectively. The white curve represents the laser excitation spot.

FIG. 9A is a graph showing the time-resolved ratio between the measured diffusivity D and exciton mobility μ (red line). The experimentally estimated incoherent exciton temperature was much lower than 300K (limit from Einstein relations). The shaded area represents the experimental D/μ range (20 uncertainty) estimated from different samples.

FIG. 9B is a graph showing the defect saturation effect on exciton drift and diffusion. The filling of the trap states is symmetric under diffusion but asymmetric for drift transport. Such trapping significantly reduces the effective D compared to the drift transport.

FIG. 9C is a graph showing numerical solutions of drift-diffusion equation with defect capture for various exciton gas temperatures, where the shaded region represents the experimental range of D/μ ratio over time. Capture leads to lower exciton gas temperature for all the cases.

FIGS. 9D and 9E are graphs showing the asymmetric filling of trap states in drift transport results in skewed exciton distribution visible in measurement and calculation, respectively, by comparing with their mirrored distribution (gray shaded area). Insets show time-resolved changes of the skewness as obtained from the third standardized moment of the exciton distributions. A skewed distribution is indicative of drift-transport and defect saturation effects.

FIG. 10A is a graph showing peak velocity for different strain gradient shows excitation-power independent exciton mobility. Data points are obtained from Gaussian fits to measured spatiotemporal maps.

FIGS. 10B and 10D are spatiotemporal maps along 1D guide (2.8 meV/μm strain gradient) and unstrained area, respectively, for excitation fluence of 2940 nJ/cm². The peak position (dashed blue line) shows enhanced velocity compared to low fluence (black dashed line, 29nJ/cm²) due to halo formation visible on an unstrained area of the same sample

FIGS. 10C and 10E are spatiotemporal maps showing numerical calculations show asymmetric (symmetric) exciton distribution as a result of Auger recombination and Seebeck currents caused by local heating of the exciton gas in presence (absence) of additional strain induced drift.

Corresponding reference numerals indicate corresponding parts throughout the several views of the drawings.

### DETAILED DESCRIPTION

Example embodiments will now be described more fully with reference to the accompanying drawings.

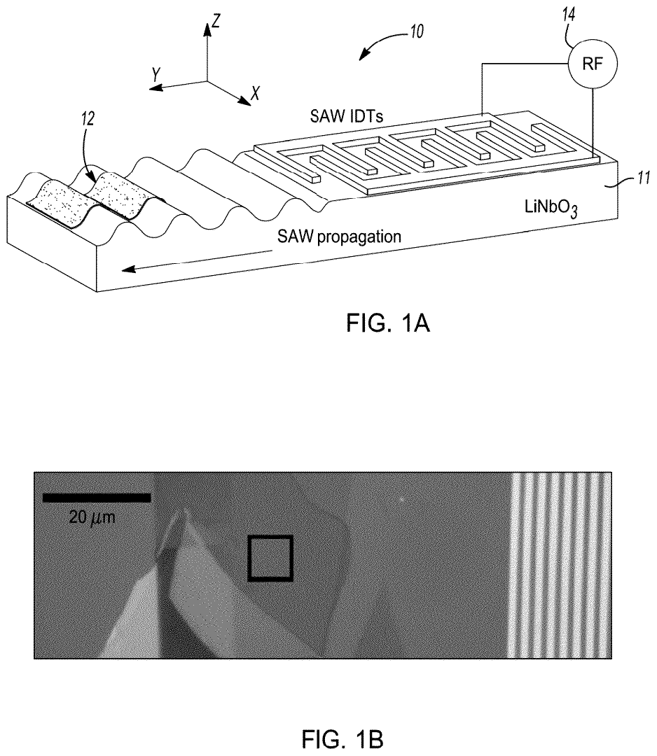

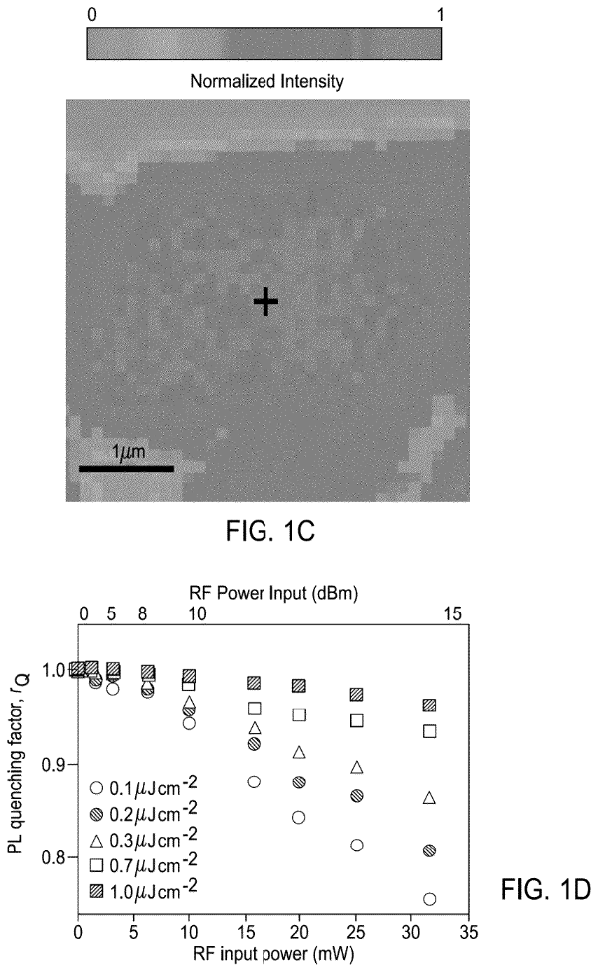

FIG. 1A depicts an example interconnect system 10 for use in a microchip. The interconnect system 10 is comprised generally of a piezoelectric substrate (bulk or waveguide geometry) 11; an excitonic material 12 supported by substrate 11; and a transducer 14 interfaced with the substrate 11. The piezoelectric substrates serves as an exciton guide. In operation, the transducer 14 operates to control transport of excitons across a surface of the exciton guide while maintaining an ambient temperature (i.e., room temperature) adjacent to the waveguide. That is, no external heating or cooling is needed to transport the excitons along the exciton guide. In one example, the excitons are directionally transported using surface acoustic wave (SAW) as further described below.

In example embodiment, the excitonic material 12 is further defined as monolayer tungsten diselenide and the waveguide is comprised of a piezoelectric material, such as lithium niobate. It is readily understood that the excitonic material may include other materials such as other transition metal dichalcogenides, carbon nanotubes, and group III-V semiconductors. Some organic materials may also be suitable for the excitonic material. Likewise, it is understood that other types of piezoelectric materials fall within the scope of this disclosure.

In the example embodiment, the transducer 14 is an AC voltage source configured to apply an AC voltage to the substrate 11. In an alternative embodiment, piezoelectric material is mechanically interfaced with the substrate 11 and the transducer applies a mechanical strain indirectly to the substrate via the piezoelectric material, such that material of the substrate can differ from the piezoelectric material of the transducer. Other implementations for the transducer are also contemplated by this disclosure.

For demonstration purposes, the example embodiment was fabricated using a standard photolithography-based metal lift-off process on a 1280 Y-cut LiNbO3 substrate. A bilayer photoresist stack was used (LOR 3A+S1813) to achieve high-resolution IDT features. The IDTs were patterned using a projection lithography tool (GCA AS200 AutoStep). After the development of the exposed features, 10 nm Cr and 100 nm Au were evaporated using the electron-beam evaporation technique. The lift-off was performed by immersing the samples in Remover PG for 12 h. The second step of lithography involved the patterning of the contact pads, which was carried out using SPR 220 (3.0) as the photoresist layer. The same projection lithography tool was used to pattern the contact pads. After the development of the exposed contact-pad features, 10 nm Cr and 480 nm Au were evaporated using the electron-beam evaporation technique. The lift-off was performed following the same process as the first step. The samples were bonded to a custom-made printed circuit board using wire bonding.

FIGS. 1B and 1C show a false-colour brightfield optical image of the sample and the PL map of the hBN-encapsulated monolayer WSe₂, respectively. Here, hBN encapsulation is critical to improve the transport properties of the excitons by suppressing non-radiative recombination processes, surface roughness, energetic disorder, and scattering from impurities and surface states. More importantly, the underlying bulk hBN moderates the dielectric environment surrounding the monolayer, thereby increasing the exciton binding energy compared with monolayer directly placed on a LiNbO₃ substrate. This reduces exciton dissociation under a SAW piezoelectric field (type-II modulation) due to increased binding energy. The dissociation can be further reduced by screening the piezoelectric field, thereby enabling the study of excitonic interactions with type-I modulation (bandgap change due to strain). In this disclosure, excitonic interactions are achieved by utilizing the optically generated free carriers to screen the in-plane electric field of the travelling SAW wave. FIG. 1D plots the PL quenching

$${r}_{Q} = \frac{{I}_{PL , RF}}{{I}_{PL , - 60 dBm}}$$

due to dissociation as a function of RF input power for various optical excitations. Here, I_{PL,RF}=∫I_{RF}(λ)dλ and I_{PL,-60 dBm}=∫I_{-60 dBm}(λ)dλ refer to the integrated PL intensity measured at a given RF input power and at −60 dBm (1 nW is the minimum RF input power used in this work), respectively. λ is the emission wavelength. The net quenching at a given RF power reduces with an increase in the optical excitation density due to optically generated free-carrier screening. Thus, the excitation optical fluence provides a knob to control the dissociation and thereby investigate the effects of type-I modulation on exciton transport.

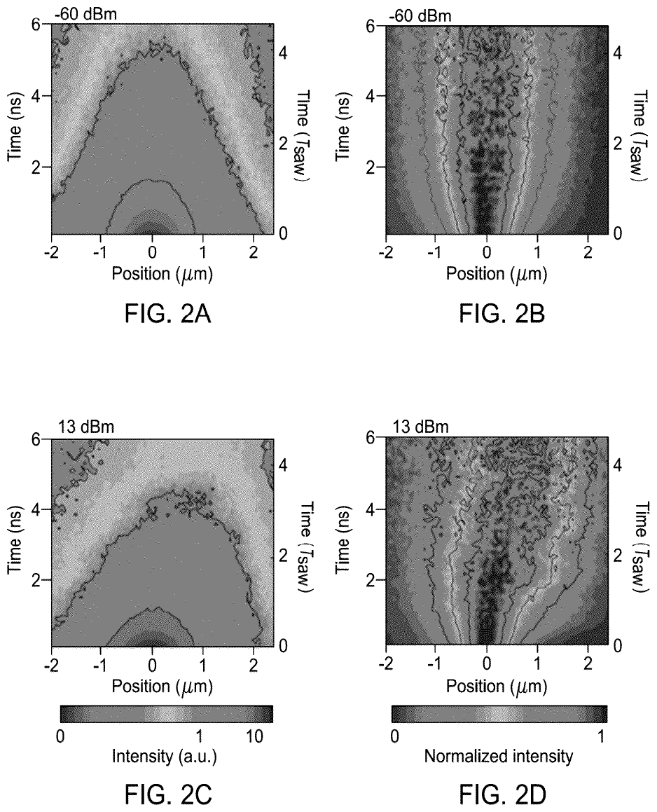

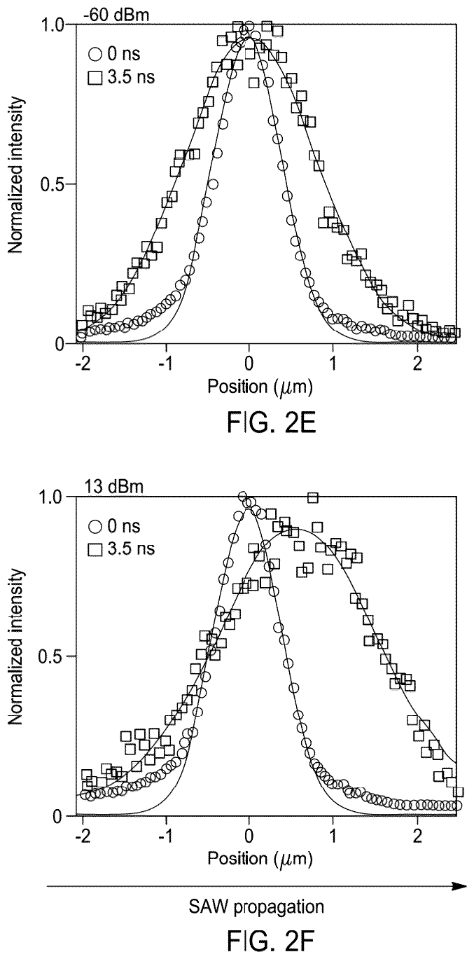

FIGS. 2A-2F show the results of excitonic energy transport measured using a scanning single photon avalanche diode (SPAD). FIGS. 2A and 2B show the spatiotemporal exciton density distributions at RF input powers of −60 dBm (~1 nW) and 13 dBm (~20 mW), respectively, at an optical fluence of 1.2 μJ cm-2 (type-l modulation dominates since PL quenching was below ~2% under the experimental conditions). FIGS. 2C and 2D show the exciton density distribution normalized along space at each time instance corresponding to the data in FIGS. 2A and 2B, respectively. The symmetric exciton density distribution at −60 dBm resembles typical anomalous exciton diffusion in monolayer WSe₂. In this case, the peak position of the distribution does not show any spatial drift with time, indicating the absence of a local strain gradient in the monolayer. When the RF excitation is turned on, the exciton density distribution shifts along the propagation direction of the SAW. Exciton density distribution at two time instances, namely, t=0 ns and t=3.5 ns, along with the Gaussian fits are shown in FIGS. 2E and 2F for RF excitations of −60 and 13 dBm, respectively. The black arrow indicates the direction of propagation.

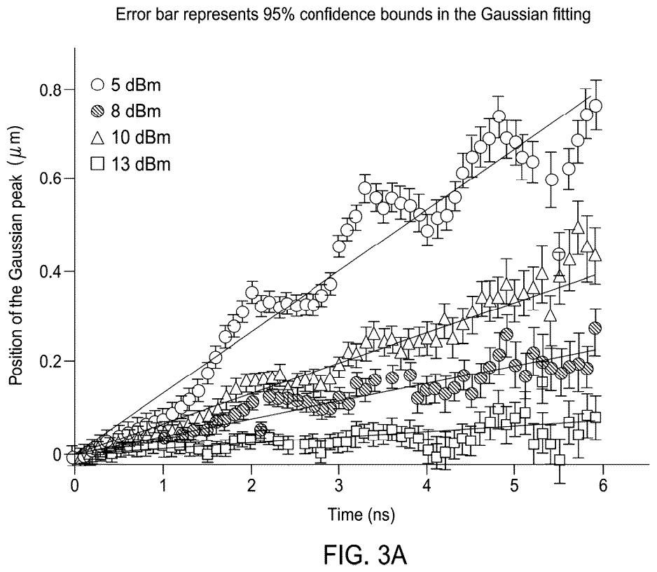

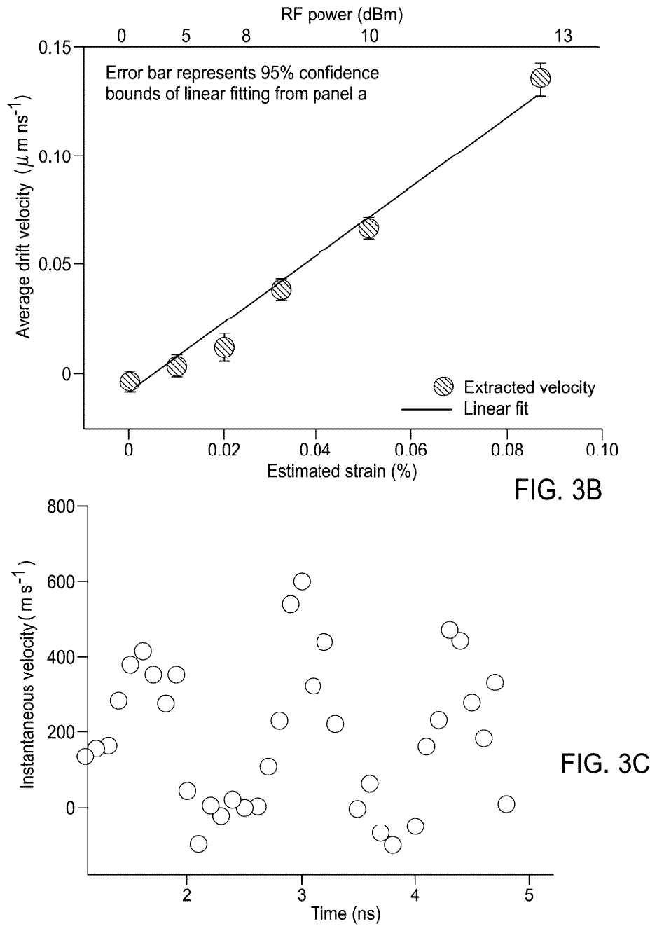

FIG. 3A shows the spatial evolution of the Gaussian exciton density peak as a function of time. With increasing RF power, one sees a gradual increase in the spatial shift. In addition, one observes periodic oscillations corresponding to the SAW period. This suggests weak coupling between the excitons and travelling strain wave, where the exciton drift velocity is insufficient to keep up with the travelling wave and hence results in a net spatial shift in the exciton density over time. The evolution of the Gaussian peak is modeled under dynamic strain over time using a linear relationship (FIG. 3a, solid line):

h(t)=v_{avg}t+h_{offset}, (1)

where h(t) refers to the net displacement of the generated exciton density over many SAW periods, v_{avg} refers to the average drift velocity of the exciton density under the applied dynamic strain and h_{offset} is a constant to accommodate the fitting error. FIG. 3B plots the v_{avg} for various volumetric strains estimated at different RF input powers. A linear trend with volumetric strain indicates a proportional increase in exciton coupling efficiency with the dynamic strain field. Further improvement in v_{avg} can be achieved by increasing the strain gradient or increasing the exciton diffusivity by suppressing scattering from impurity states and surface roughness.

Next, the extent of exciton coupling to the dynamically varying strain field of the SAW is determined by estimating the instantaneous velocity from the measured instantaneous displacement of the exciton density. The time derivative of the measured displacement at RF input power of 13 dBm gives the instantaneous velocity of the exciton flux (FIG. 3C). The instantaneous drift velocity reaches a maximum value of 600 ms⁻¹, which is smaller than the SAW velocity (v_{SAW}) in LiNbO3 (3,979 ms⁻¹). Since the maximum drift velocity of the exciton flux is nearly six times smaller than the acoustic wave velocity (v_{max,13dBm}<v_{SAW}), the exciton flux cannot keep pace with the travelling strain wave (weak coupling regime). This results in asymmetric exciton funneling (in opposite directions) during each SAW period. Hence, one observes oscillations in the peak position of the exciton distribution and a net spatial shift over time in the direction of the travelling strain field (FIGS. 2D and 3A). The observation closely resembles carrier drift under a dynamic electric field in the weak coupling regime presented elsewhere. Under strong coupling, the excitons would funnel to the lowest potential, followed by transport of the trapped excitons with the strain wave. In such a case, the transport distance is expected to be limited by the radiative lifetime and sample size.

Under a dynamically varying strain field, the maximum exciton drift velocity can be written as

$${v}_{m ax} = μ \vert \frac{\partial {E}_{g}}{\partial ε} \vert \frac{\partial ε}{\partial x} \vert max = μ \vert \frac{\partial {E}_{g}}{\partial ε} k {ε}_{0} , \qquad ( 2 )$$

where

$$μ , \frac{\partial {E}_{g}}{\partial ε} , k = \frac{2 π}{{λ}_{SAW}}$$

and ε₀ refer to the exciton mobility, strain sensitivity of the monolayer bandgap, acoustic wave momentum and maximum dynamic strain in the monolayer, respectively. Here, λ_{SAW} refers to the wavelength of the acoustic wave (λ_{SAW}=4.7 μm). Based on the measured PL quenching (FIG. 1D), calculate the maximum dynamic strain amplitude (co) to be ~+0.086% (tension) at RF power of 13 dBm using the converse piezoelectric matrix of 128° LiNbO₃ and the estimated piezoelectric field in the substrate. Using the estimated value of the maximum drift velocity at RF input power of 13 dBm (600 ms⁻¹, which is about 15% of the SAW velocity) in equation (2), extract the exciton mobility in the monolayer to be 900 cm² (eV s)⁻¹. The extracted exciton mobility is nearly two orders lower (exceeding 104 cm² (eV s)⁻¹ compared with indirect excitons in III-V quantum well structures at cryogenic temperatures that show long-range transport. The small exciton mobility, resulting from scattering with defects and phonons at room temperature, along with the short radiative lifetime result in a smaller transport distance (approximately micrometres) under a dynamic strain in monolayer TMDs. However, the results show the potential of the material system for future room-temperature excitonic devices, especially as defect densities get lowered with rapid progress in material growth.

Note that the total bandgap modulation (δE_{g}=2×0.086×60=10.3 meV) is smaller than the room-temperature thermal energy (25.7 meV). However, the observed directional transport primarily results from the combination of the strong bandgap sensitivity of TMD monolayers and the strain gradient generated by the SAW wave, which leads to drift dominating over diffusion transport at room temperature. At the same time, assume a negligible decoupling of the dynamic strain to the WSe₂ monolayer through the underlying hBN flakes due to the high mechanical strength and small thickness (20-30 nm; measured using white-light interferometry) compared with the acoustic wavelength (4.7 μm). Therefore, the extracted values of the average drift velocity set the lower limit at room temperature. One also expects negligible contributions to the observed transport from strain-induced change in the binding energy of neutral excitons as such modulations are substantially smaller compared with strain-induced bandgap modulation based on theoretical calculations. Finally, one can expect negligible contribution to the quasiparticle conversion (exciton to trion) under strain and type-II bandgap modulation due to the much lower strain amplitude (<0.1%) and screening due to the underlying hBN spacer.

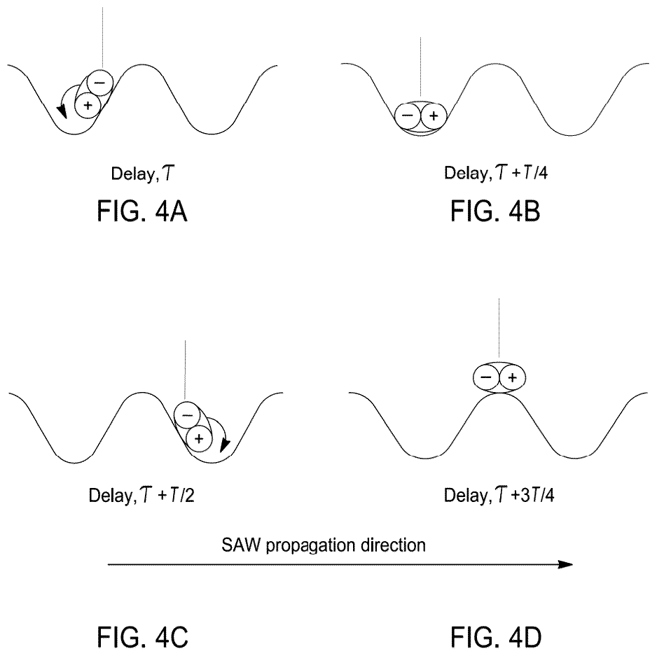

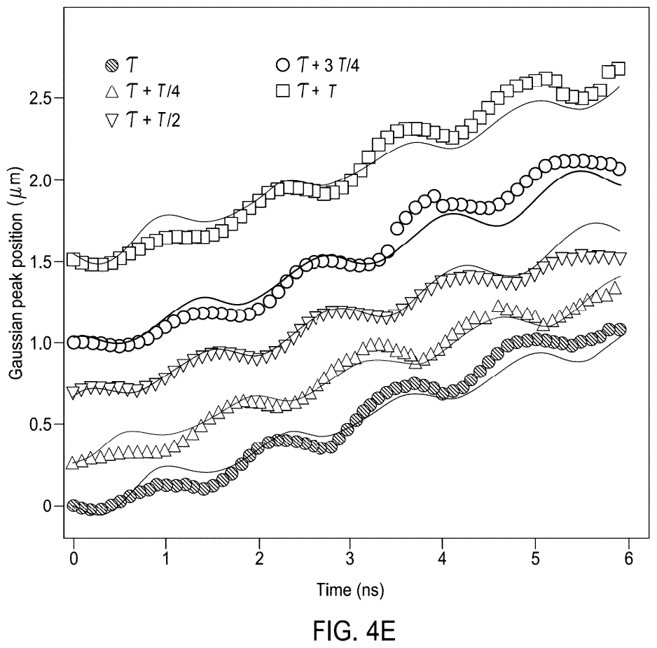

Exciton transport under type-I modulation takes place by spatial trapping at the minimum energy locations. FIGS. 4A-4D show the schematic for the exciton potential under a dynamic strain field. This disclosure verified that the observed spatiotemporal modulation in the exciton density is due to type-I modulation by performing three experiments. First, conduct transport measurements at an order lower optical fluence. Since the effective mobility of the photogenerated excitons increase with optical fluence, the excitons experience efficient coupling with the travelling strain field at high optical excitation densities. For the same set of RF powers (constant strain), it was observed reduced modulation in the exciton density and a decrease in average exciton spatial drift for lower optical fluence. Second, the time-resolved photoluminescence (TRPL) was measured as a function of optical fluence. At low fluence, the TRPL decays faster with an increase in RF power due to increased ionization (additional decay) resulting from type-II modulation. At high fluence, the reduction in the TRPL decay rate is slower, confirming the screening of the in-plane piezoelectric field by the free carriers. Under this condition, type-I modulation dominates and the TRPL oscillates at the SAW frequency. The strain-induced oscillations result from the dynamic modulation of the energy separation between the K and Q valleys under the travelling strain wave. Finally, verify type-I band-edge modulation by extracting the neutral-exciton linewidth broadening, which remains constant for varying optical excitation fluences under RF excitation. It is also noted that the observations have been reproduced on multiple samples with different RF resonance frequencies.

The dynamic acoustic strain field generated by a SAW wave can be represented by

ε(x,t)=ε₀ cos(ωt−kx+φ), (3)

where ε₀ refers to the amplitude of the strain field, ω refers to the angular frequency (ω=2πf_{SAW}; f_{SAW} refers to the acoustic resonance frequency) and φ refers to the instantaneous phase of the acoustic wave. Therefore, for a given optical excitation position from the IDT, the generated exciton density interacts with a certain phase of the travelling strain field. Using equation (3), the dynamic strain-induced drift velocity of the exciton flux can be written as

$${v}_{ex} ( x , t ) = {μ}_{ε} \frac{\partial ε ( x , t )}{\partial x} = {μ}_{ε} k sin ( ω t - kx + φ ) \qquad ( 4 )$$

where

$${μ}_{ε} = μ \frac{\partial {E}_{g}}{\partial ε}$$

refers to the strain mobility of the excitons. At photoexcitation (t=0), the instantaneous velocity of the exciton flux is a function of the acoustic phase, namely, vₑₓ(x,0)=μ_{ε}k sin(ωt−kx+φ). Therefore, precise control over the direction of photogenerated exciton flux can be achieved by controlling the relative phases (see, FIGS. 4A-4D. Such control is achieved by introducing a delay

$$τ ( φ = \frac{2 π}{T} ; T = \frac{1}{{f}_{SAW}} )$$

in the laser trigger signal. FIG. 4E plots the spatiotemporal evolution of the centre of the exciton density distribution as a function of time delay (t) with increments of T/4, which were further numerically modelled using the following modified drift-diffusion equation:

$$\frac{\partial {n}_{ex} ( x , t )}{\partial t} = {D}_{ex} \frac{{\partial }^{2} {n}_{ex} ( x , t )}{\partial {x}^{2}} + \frac{\partial ( {v}_{ex} {n}_{ex} ( x , t ) )}{\partial x} + G - \frac{{n}_{ex} ( x , t )}{{τ}_{ex}} - \frac{{n}_{ex} ( x , t )}{{τ}_{ion}} , \qquad ( 5 )$$

Here nₑₓ, Dₑₓ, vₑₓ, τₑₓ and τᵢₒₙ refer to the population, diffusion coefficient, velocity, recombination time and ionization time of the neutral exciton, respectively. Further, G refers to the photogenerated exciton density under optical excitation. The solid lines in FIG. 4E are the fits from the numerical simulation that successfully capture the observed dynamics. Consistently, it was observed similar progressive evolution with the instantaneous phase in the TRPL data.

In an alternative approach, strain-based exciton guides are explored. For example, in a tungsten diselenide (WSe₂) monolayer at room-temperature, the 1 s-exciton distribution n₁ₛ(x, y, t) in space (x, y) and time (t) is measured. When excitons are generated at x=0 and translated towards right, it was determined the exciton density

$${n}_{right} ( t ) ≡ {\int }_{0}^{∞} dx {\int }_{- ∞}^{∞} dy {n}_{1 s} ( x , y , t )$$

on the right-hand side of the excitation and compared to the remaining density in the left-hand side, n_{left}(t). Drift visibility is quantified as

$$η ( t ) ≡ \frac{{n}_{right} ( t ) - {n}_{left} ( t )}{{n}_{right} ( t ) + {n}_{left} ( t )} . \qquad ( 6 )$$

Experiment-theory investigations demonstrate directional exciton flux with η(t) reaching up to 38% at low exciton densities. The transport is guided in one dimension and features several possible advantages for improved transport efficiency. In particular, it was shown that exciton capture does not affect mobility much when it reduces diffusion by an order of magnitude compared to thermodynamic Einstein relation. As a result, excitons remain more localized than expected at room temperature, which yields significantly enhanced η(t) and improved drift transport.

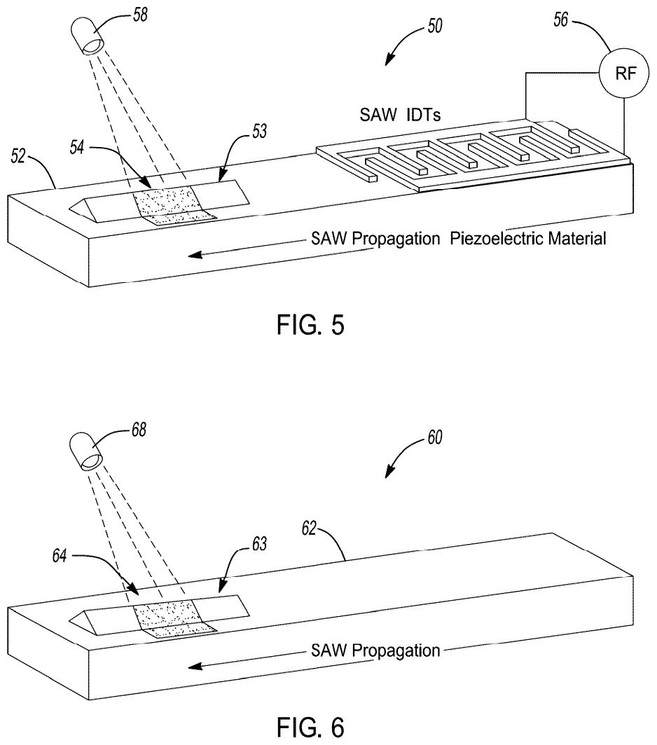

FIG. 5 depicts an example interconnect system 50 based on this operating principle. The interconnect system 50 is comprised generally of an exciton guide 52 having a ridge 53 formed on a surface thereof; an excitonic material 54 disposed on the surface of the exciton guide 52; and a transducer 56 interfaced with the exciton guide 52. The transducer 56 controls the transport of excitons along the ridge 53 of the exciton guide 52 using surface acoustic waves. In one implementation, the exciton guide 52 is a piezoelectric material and the transducer 56 is an AC voltage source configured to apply an AC voltage to the piezoelectric material to create the surface acoustic waves.

To generate excitons, the interconnect system 50 further includes an exciton source 58 configured to create excitons along the ridge of the exciton guide 52. In one example, the exciton source 58 is a light source that projects light onto the excitonic material and thereby generates excitons. In another example, the exciton source 58 is an electrical source that injects carriers onto the exciton guide 52. Other types of exciton sources are also contemplated by this disclosure.

In example embodiment, the excitonic material 54 is further defined as monolayer tungsten diselenide and the exciton guide 52 is comprised of a piezoelectric material, such as lithium niobate. It is readily understood that the excitonic material may include other materials such as other transition metal dichalcogenides, carbon nanotubes, and group III-V semiconductors. Some organic materials may also be suitable for the excitonic material. Likewise, it is understood that other types of piezoelectric materials fall within the scope of this disclosure.

Another example embodiment of the interconnect system 60 is shown in FIG. 6. In this embodiment, the interconnect system 60 includes an exciton guide 62 and an exciton source 68 but not a transducer. More specifically, the exciton guide 62 has a ridge formed on a surface thereof, where the ridge has a unidirectional grade from one end to the other end. An excitonic material 64 is disposed on the surface of the exciton guide 62, and the exciton source 68 is configured to create excitons along the ridge of the exciton guide 62. The mechanical strain along the ridge of the exciton guide 62 causes the excitons to move along the ridge of the exciton guide 62. Experimental and computational results for this embodiment are set forth below.

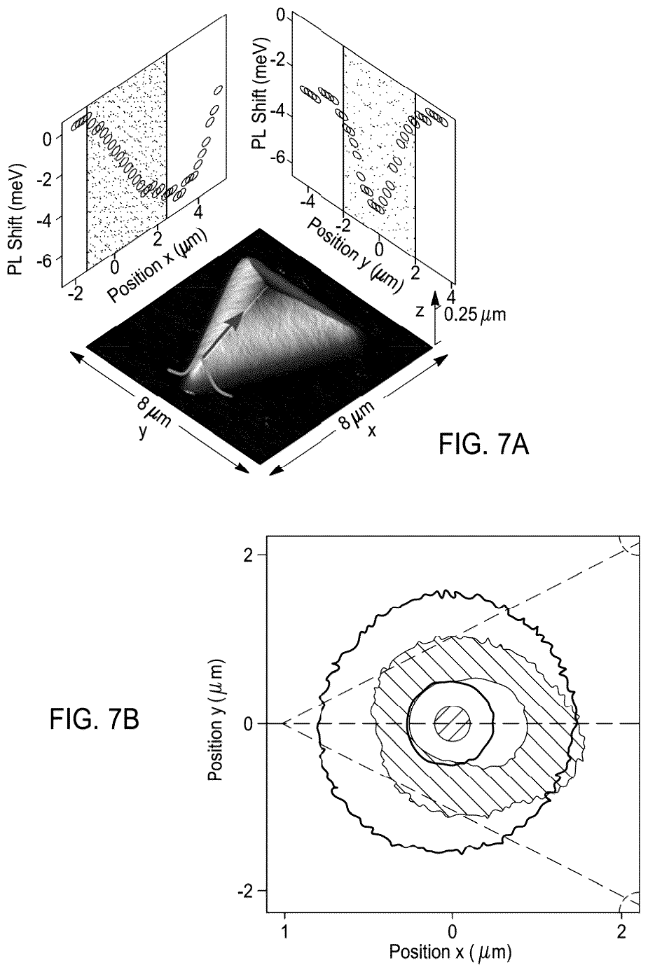

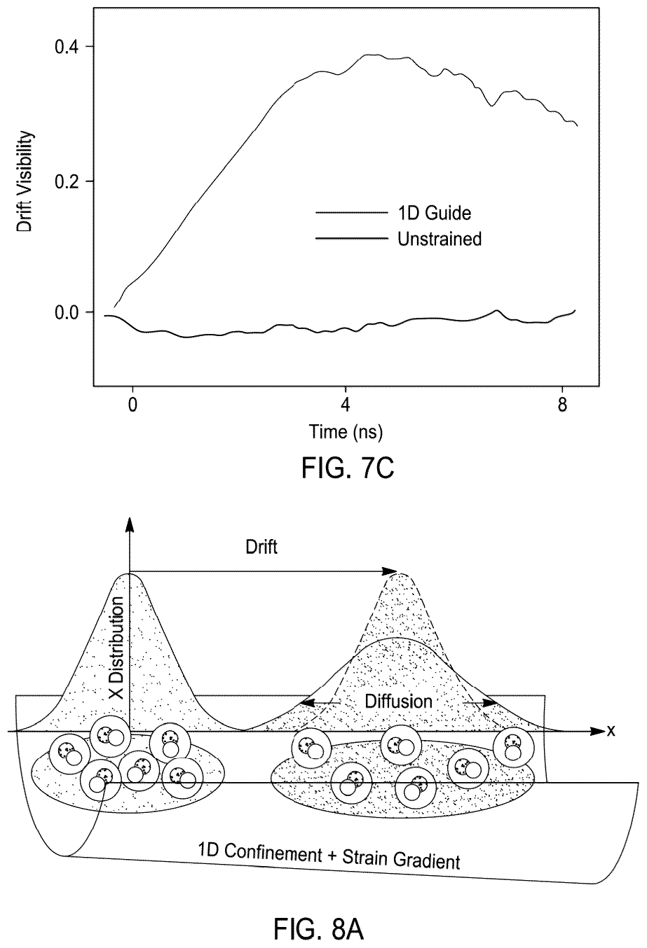

FIG. 7A shows an atomic force microscope (AFM) scan of a representative sample with a WSe₂ monolayer transferred onto a tapered nanoridge having 6 μm×6 μm in lateral dimension with the tallest point on the nanoridge being 250 nm above the base. Nanoridges of different aspect ratios were fabricated on a Si-SiO₂ substrate using photolithography followed by wet etching using a receding mask in buffered oxide etch. The tapered nanoridge generates a unidirectional gradient (red arrow) in the exciton potential along the x direction and confinement (green curve) along the y direction. Estimate the resulting modulation of the exciton potential in the x and y directions using spatially resolved photoluminescence (PL) measurements. Specifically, one can determine the shift in PL energy, E_{PL}, shown in FIG. 7A as red and green circles; the shaded region corresponds to the intended 1D guide. This PL shift corroborates that the x direction exhibits asymmetric strain (potential) whereas the y direction yields a symmetric strain (confinement) potential for the excitons. These results are also consistent with the expected tensile-strain profile; it is maximum at the apex of the nanoridge coinciding with maximum of the PL shift. An identical shape of the PL spectra along the nanoridge rules out that strain created new quasiparticle resonances (exciton-trion) below the exciton.

This change in the energy landscape results in a 1D guide where the excitons are unidirectionally driven towards the lowest potential in space (red arrow). To verify the 1D-exciton guide operation, FIG. 7B shows intensity map of the time-integrated PL emission when excited on the nanoridge (yellow and white regions represent 10% and 50% peak PL intensities respectively). The outer circles outline the corresponding PL emission contours from an unstrained area from the same monolayer excited under the same low laser fluence (29.4 nJ/cm²). The inner circle shows the region of the excitation laser at 50% peak value. It was observed that the nanoridge position produces 23% narrower PL emission in the y direction than the unstrained position, which is consistent with confinement. This confinement increases as one moves along the guide due to deeper confinement potential with elevation. In the x direction, the peak of the integrated PL is asymmetric, which confirms the unidirectional exciton transport along the intended 1D guide. The 10% contour comparison highlights the directionality whereas the 50% contours accentuate the confinement. In FIG. 7C, drift visibility is quantified over time as defined in Eq. (6) and observed that it reaches a maximum value of 38% at around 4.5 ns.

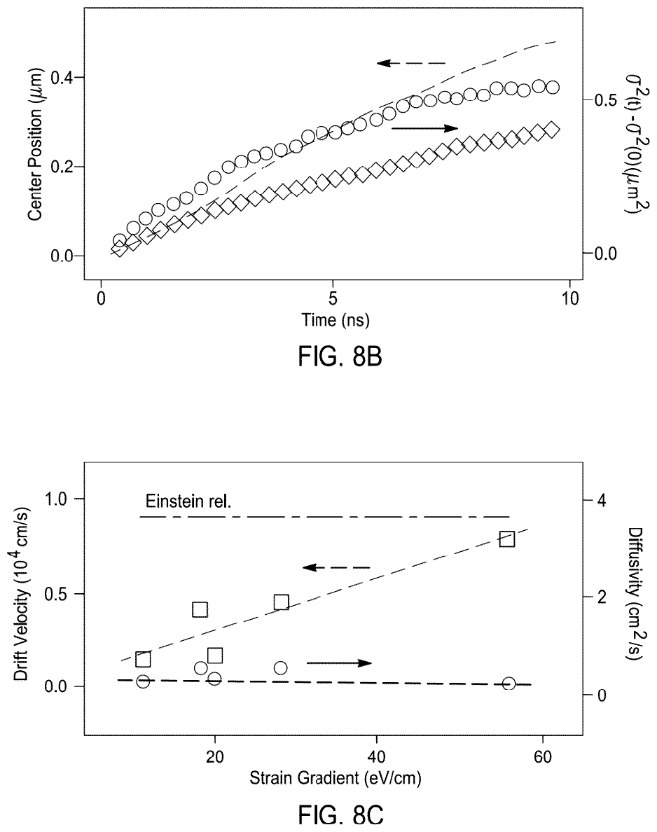

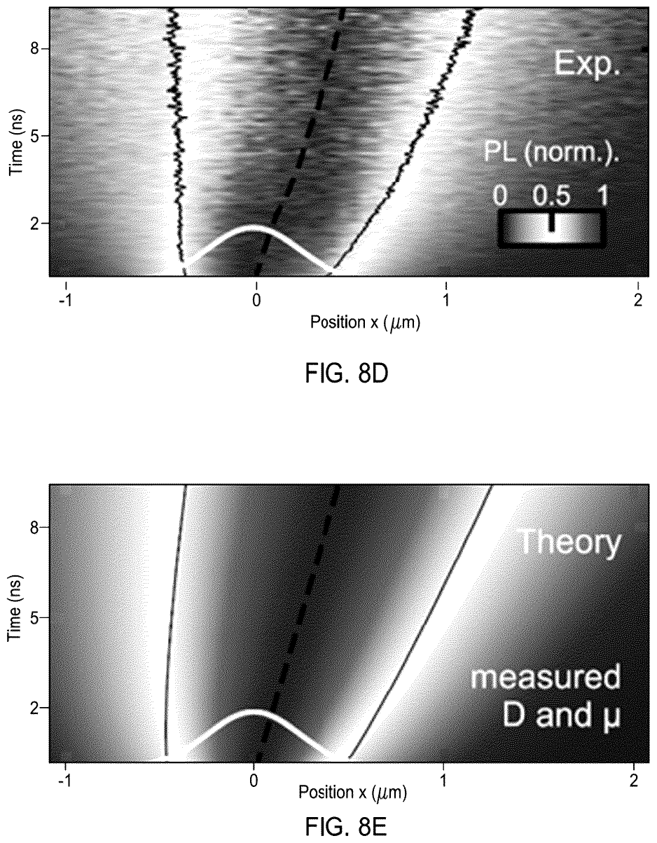

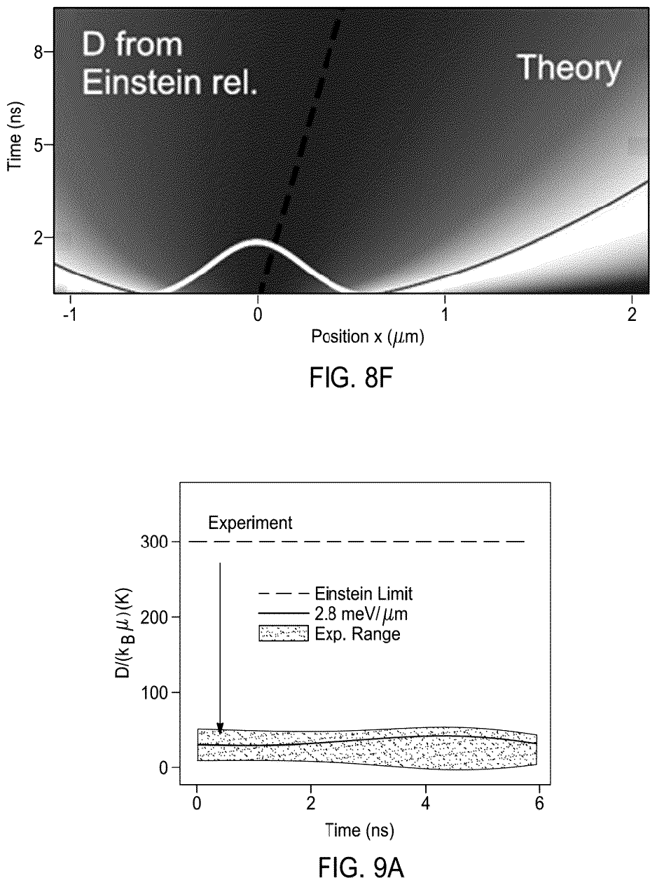

FIG. 8A shows the schematic of exciton transport with contribution from diffusion and drift, where diffusivity (D) broadens the distribution symmetrically and drift results in a net spatial shift, x_{shift}, of the whole distribution. In steady state, velocity v=x_{shift}/t=μF defines mobility μμ at time t for a known force

$$F = \frac{{dE}_{PL}}{dx}$$

(see FIG. 7A) induced by the energy gradient of the nanoridge. As a key feature of diffusion, D determines the rate of change,

$${σ}_{x}^{2} ( t ) - {σ}_{x}^{2} ( 0 ) = 2 Dt ,$$

in the squared width (variance) of a distribution σₓ(t), standard deviation of a Gaussian. Our spatially, temporally, and spectrally resolved PL distributions provide σₓ(t), x_{shift}, and F so that we can independently measure both u and D for different nanoridge configurations.

First analyze low-excitation conditions (58.9 nJ/cm²) at room temperature; it was verified that the measured PL scales linearly with fluence. Thus, the resulting PL intensity at a given position and time PL (x, t) directly maps the distribution of exciton density, n₁ₛ(x, t), because it dominates over nonlinear PL from electron-hole plasma. The excitation spot is near the lower tip of the tapered nanoridge. Next, scan a single photon avalanche diode (SPAD) along (FIG. 7A, red arrow, x direction) and perpendicular (FIG. 7A, green curve, y direction) to the nanoridge to measure n₁ₛ(x, t) or n₁ₛ(y, t) maps, respectively. To accurately determine the motion, and distribution dynamics, extract the peak position and construct the first-order and second-order moments of the nis distribution. While observing no y motion, the peak of nis moves linearly towards the maximum strain position (peak of the tapered nanoridge), as shown by the dashed curve in FIG. 8A. This major difference in x versus y motion demonstrates the concept of 1D exciton guide where asymmetric strain gradient is utilized to direct the exciton flux at room temperature. Initially, the first moment of x (squares) follows the peak position, but it begins to lag after 2 ns, indicating a change in the distribution profile. Also, the measured

$${σ}_{x}^{2} ( t ) - {σ}_{x}^{2} ( 0 )$$

(circles) follows almost a linear slope within the time frame. The resulting time derivatives of the first-order and second-order moments produce drift velocity (v) and D. The spatial shift of exciton energy defines gradient of energy (force F=2.8 meV/μm).

Repeat the measurement and analysis of FIG. 8B for multiple samples with different strain gradients to quantify μ and D as function of strain gradient (quantified by F). Specifically, one has nanostructured a series of samples with different nanoridge heights to change the strain gradient. FIG. 8C plots the measured drift velocity (red squares, extracted from data up to t=2 ns after a nonresonant excitation) for five different samples, revealing a linear relation between the exciton drift velocity and F. The resulting v/F yields a constant exciton mobility μ=169±39 cm²/(eV s) in the monolayer. The simultaneously measured D (squares) is nearly independent of F, and should be connected with u via the well-known Einstein relation

$$\frac{D}{μ} = {k}_{B} T , \qquad ( 7 )$$

with temperature T and Boltzmann constant K_{B}. The dash-dotted line shows diffusivity, D_{Einstein}, constructed from measured μ and Eq. (6) at T=300K; the measured D is roughly 20 times smaller than D_{Einstein}, demonstrating that the TMD system massively violates the expected Einstein relation.

To confirm this unexpected violation in more detail, we plot the measured spatio-temporal n₁ₛ(x, t) map in FIG. 8D; each x slice of n₁ₛ(x, t) normalized to produce a constant peak intensity for all t. For comparison, the white line indicates the laser excitation profile and the black dashed and solid curves represent the peak position and one standard-deviation (σₓ) of the distribution, respectively. Compare the corresponding, computed n₁ₛ(x, t) maps in FIGS. 8E and 8F using the measured D and D_{Einstein}, respectively, in the exciton drift-diffusion-transport equations having the measured Fis strain profile as the driving force for exciton transport. Observe that computation using D_{Einstein} produces an overwhelming broadened n₁ₛ(x, t) compared to the experiment, whereas using D replicates experiments in detail, except the slight slowdown of experimental drift after 2 ns (compare black dashed lines). This intriguing effect introduce the 20-fold slowdown of diffusion in the TMD samples and also improves the quality of drift transport, albeit still need to determine the physical mechanism behind the breakdown of the Einstein relation.

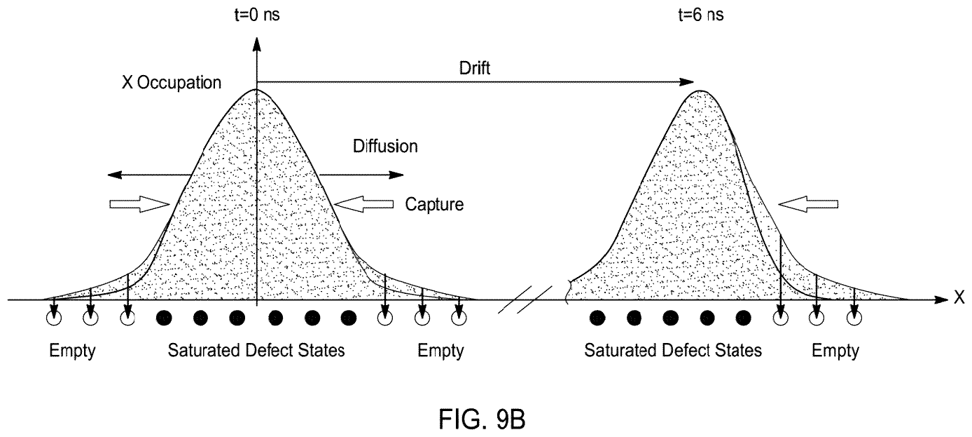

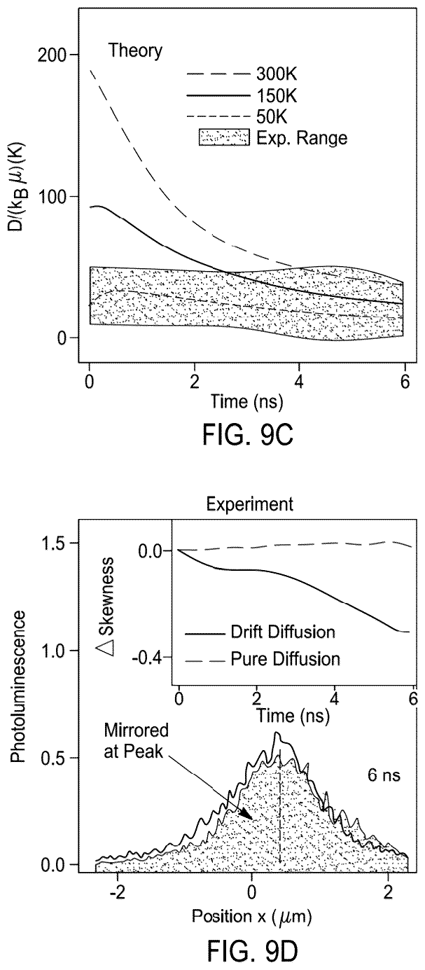

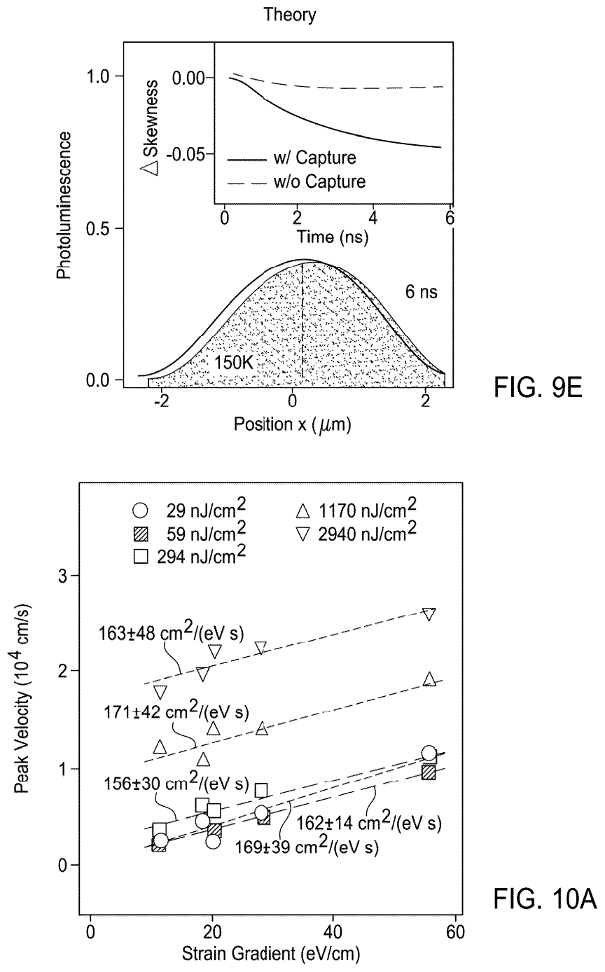

To explore the non-thermal D/μ dynamics, FIG. 9A shows the measured D/μ as function of time. According to Eq. (7), the thermal nature of D/μ can be assessed when plotting it in units of temperature. The red line is for a sample with a strain gradient of F=2.8 meV/μm and is a representative for three different samples producing a 20 experimental uncertainty indicated by the shaded area. Confirm again that the D/μ temperature extracted from combined transport-diffusion measurements is well below room temperature (dashed line) suggested by the Einstein relation (2); also, this analysis verifies a major breakdown of the Einstein relation—the measured D/μ corresponds to about 20-times smaller T (black arrow) than room temperature.

The deviation of the centroid from the peak position in FIG. 8B provides key evidence to understand the breakdown of Einstein relation. Carefully explore whether saturable exciton capture by defects could explain this dramatic reduction in D and T because defects are abundant in TMDs and can induce capture which is known to violate Einstein relation. FIG. 9B illustrates the key effects of saturable capture on D and μ. Since capture rate is roughly proportional to local exciton density, it is strongest at the peak of n₁ₛ(x,t); once captured, exciton motion should stop. After creation of n₁ₛ(x,t), capture quickly (t=0 ns) creates filled trap states (black-filled circles) in the middle of the distribution and leaves defects mostly empty (open circles) in the tails. Once the middle defects saturate (become filled), the exciton capture continues only at the tails (vertical arrows). This tends to effectively shrink (lower horizontal arrows) the width of n₁ₛ(x,t) as mobile excitons are removed from the tails of n₁ₛ(x,t), which also counteracts diffusion's (upper horizontal arrows) tendency to broaden n₁ₛ(x,t). These opposing processes produce an effectively reduced D. At the same time, the capture should not affect drift and u much because capture at both ends of the tails does not affect the centroid motion. Thus, saturated capture can indeed lead to major decrease in D/μ as observed in FIGS. 8A-8F. Additionally, one expects the distribution to become skewed when the center of n₁ₛ(x,t) has translated significantly (t=6 ns schematics) in the 1D guide. In this scenario, only the front edge of n₁ₛ(x,t) moves to a region with unsaturated defects where it experiences significant capture. We expect this arising asymmetry to reshape the leading edge of n₁ₛ(x,t) to become steeper than the trailing edge, introducing forward-leaning skewness.

To quantify the capture-predictions above, add a simple exciton-capture description by saturable defects to the exciton drift-diffusion-transport equations. FIG. 9C shows the computed D/μ ratio for postulated exciton-gas temperatures of T=300K (dashed line), T=150 K (red line), and T=50K (dotted line). In all three cases, exciton capture significantly lowers D/μ towards the experimentally measured range (shaded area), 7 K-50 K, corresponding to factor 43 to 7.6 below the Einstein relation. Without defects, D/μ becomes constant, matching the T value. Simple capture description reproduces the late-time D/μ remarkably well for all the representative T, while T below 150 K is needed to predict the early onset. One expects that a more microscopic description of the capture process, especially how the capture kinetics affects the exciton temperature, is needed to track these experimental details beyond the simple description used here. Nevertheless, exciton capture is identified as the key process that decreases D/μ well below the prediction of the Einstein relation (2).

To determine additional qualitative effects by saturable defects, analyze n₁ₛ(x,t) distributions further, namely the onset of skewness. FIGS. 9D and 9E show the measured photoluminescence and computed exciton distribution n₁ₛ(x,t) (assuming T=150 K), respectively, at t=6 ns after excitation. Both measured and computed distributions (line) show significant skewness, revealed by comparing with the mirrored distribution (gray shaded area). The vertical dashed line indicates the peak position of the distribution. Insets show the temporal skewness changes, Δₜ skewness=skewness (t)−skewness (t=0), of the measured and calculated distribution for sample with (solid line) and without (dashed line) 1D guide (strain gradient) for experiment or without capture (dashed line) for computations. Negative skewness is indicative of forward-leaning distribution. Consistent with translation under saturable capture, both experiment and theory produce the same qualitative outcome—drift induces forward-leaning skewness as predicted in FIG. 9B. The more non-Gaussian shape of the experiment stems likely from the simplicity of the exciton capture description, which nonetheless predicts the key features of saturable capture—the massive violation of the Einstein relation and the buildup of forward-leaning skewness upon transport.

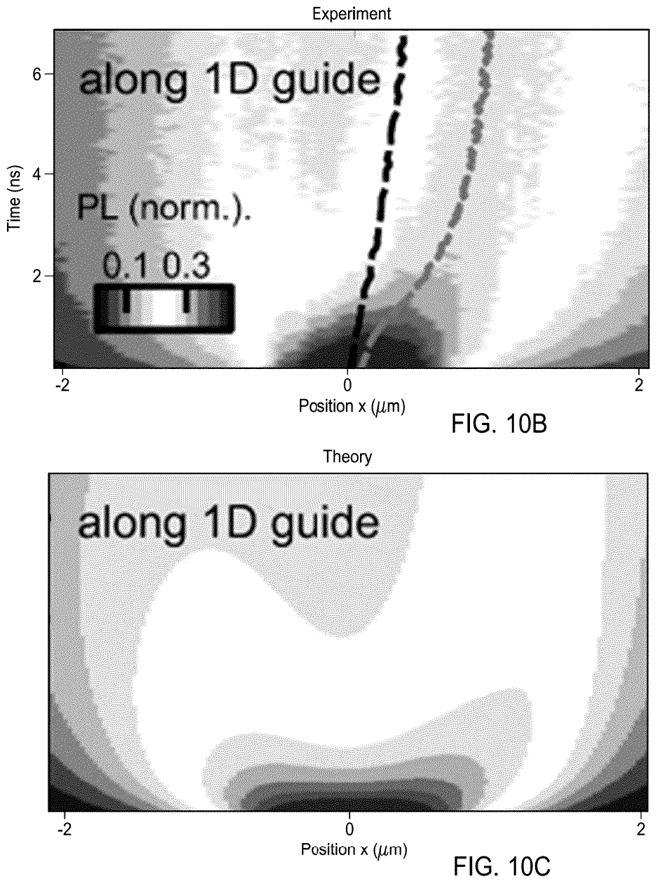

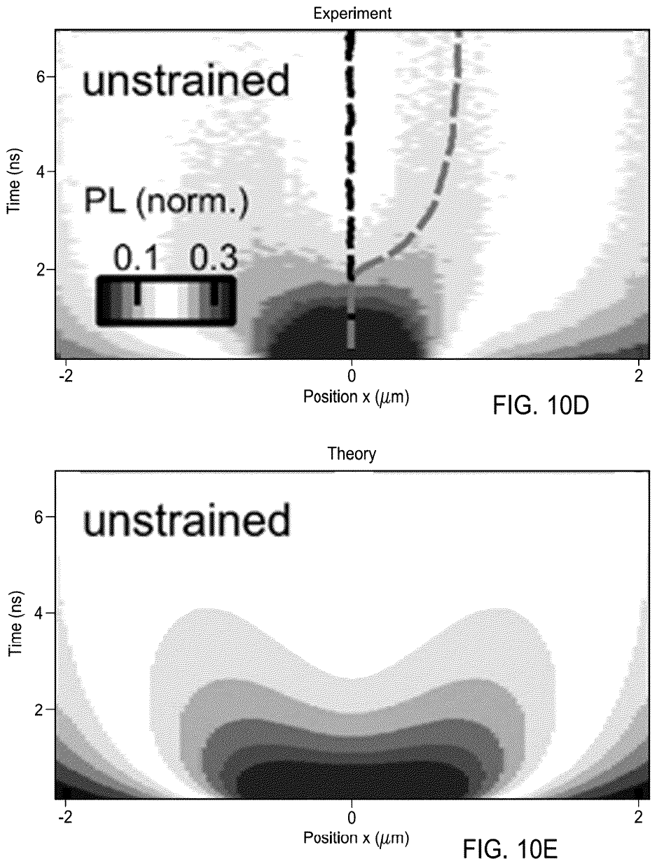

Experiments were also conducted at high excitation fluences (up to 100 times those used in FIGS. 8 and 9) to quantify the contributions from nonlinear effects on directional transport. It is well known that high excitations start deforming the exciton distribution due to halo formation via many-body effects. In this connection, it is interesting to explore whether these effects could improve the transport efficiency. One can also determine the effective u and D details from the right-hand side of the n₁ₛ(x>0, t) by using Gaussian fits instead of moments to exclude the distortions at x<0. FIG. 10 shows the resulting peak velocity for different strain gradients at various fluences. For each sample, the transport velocity monotonically increases beyond a threshold value suggesting nonequilibrium many-body contributions indeed increase the transport. The enhanced transport distance corroborates this observation.

As a new feature, one finds that the velocity does not approach zero for vanishing rain (F₁ₛ=0), but follows

v=μF₁ₛ+v_{exc}, (8)

where v_{exc} is the fluence-dependent excess velocity due to the strong-excitation effects. A linear fit over multiple strain gradient samples reveal essentially fluence-independent mobility values 162±14 cm²/(eVs), 156±30 cm²/(eV s), 171±42 cm²/(eVs) and 163±48 cm²/(eVs) under laser fluence of 59 nJ/cm², 294 nJ/cm², 1170 nJ/cm² and 2940 nJ/cm² respectively, in agreement with the low-fluence data. The y-intercept produces v_{exc} as function of fluence. Traditionally (for unstrained samples), the effective improvement in transport with incident laser fluence/exciton density has been attributed to increased exciton diffusivity. The results demonstrate that such analyses are severely distorted by the μ-independent v_{exc}. In other words, such an approach overestimates the diffusivity because contributions from v_{exc} (increased symmetric due to strong-excitation effects) are also included to μ. Characterizing transport that is spatially symmetric cannot decouple the effects as shown in FIG. 10B. The asymmetry introduced by the 1D guide, provides a proper platform to systematically quantify the drift velocity and the real μ at zero strain (under nonequilibrium many-body effects), as the F₁ₛ→0 limit of the measurements.

To observe the n₁ₛ(x,t) distribution details, the measured and computed n₁ₛ(x,t) map are plotted at high-excitation fluence (2940 nJ/cm²) for sample with 2.8 meV/μm strain gradient in FIGS. 10B (measurements) and 10C (theory). Experiment-theory analyses agree and both confirm that an asymmetric halo builds up over time. The centroid position (lighter dashed line) shows enhanced drift velocity compared to low-excitation (29.4 nJ/cm²) measurements on the same sample (darker dashed line). Halo formation has been related to local heating that is caused by nonradiative Auger recombination of excitons. While Auger effects predominantly recombine at the high-density central region of the distribution, the locally increasing temperature causes an additional Seebeck current that pushes the distribution outwards. Strain induces an additional, additive drift current forcing an asymmetry of the halo. However, it was consistently found that the estimated exciton mobility is within the error bar for all the excitation fluences.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. An interconnect system for use on a microchip, comprising:
an exciton guide having a ridge formed on a surface thereof;
an excitonic material disposed on the surface of the exciton guide;
an exciton source configured to create an exciton along the ridge of the exciton guide; and
a transducer interfaced with the exciton guide and operable to control transport of the exciton along the ridge of the exciton guide using surface acoustic waves.

2. The interconnect system of claim 1 wherein the excitonic material is further defined as a transition metal dichalcogenide.

3. The interconnect system of claim 1 wherein the excitonic material is selected from a group consisting of transition metal dichalcogenidse, carbon nanotubes, organic semiconductors, and group III-V semiconductors.

4. The interconnect system of claim 1 wherein the exciton guide is a piezoelectric material and the transducer is an AC voltage source configured to apply an AC voltage to the piezoelectric material.

5. The interconnect system of claim 4 wherein the excitonic material is further defined as monolayer tungsten diselenide and piezoelectric material is lithium niobate.

6. The interconnect system of claim 1 wherein the excitonic source is a light source configured to project light onto the excitonic material.

7. The interconnect system of claim 1 wherein the excitonic source is an electrical source configured to inject carriers onto the exciton guide.

8. The interconnect system of claim 1 wherein the exciton guide interconnects two circuit components on the microchip.

9. An interconnect system for use on a microchip, comprising:
an exciton guide having a ridge formed on a surface thereof, where the ridge has a unidirectional grade from one end to the other end;
an excitonic material disposed on the surface of the exciton guide; and
an exciton source configured to create an exciton along the ridge of the exciton guide, such that the exciton moves along the ridge.

10. The interconnect system of claim 8 wherein the excitonic material is further defined as a transition metal dichalcogenide.

11. The interconnect system of claim 8 wherein the excitonic material is selected from a group consisting of transition metal dichalcogenidse, carbon nanotubes, and group III-V semiconductors.

12. The interconnect system of claim 8 wherein the excitonic source is a light source configured to project light onto the excitonic material.

13. The interconnect system of claim 8 wherein the excitonic source is a light source configured to project light onto the excitonic material.

14. The interconnect system of claim 8 wherein the exciton guide interconnects two circuit components on the microchip.

15. A method for transporting energy within a microchip, comprising:
providing an exciton guide that interconnects two circuit components on the microchip, the exciton guide having a ridge formed on a surface thereof;
disposing an excitonic material on the exciton guide;
generating an exciton along the ridge of the exciton guide; and
creating a mechanical strain along the ridge of the exciton guide, thereby transporting the exciton along the ridge of the exciton guide.

16. The method of claim 14 further comprises maintaining an ambient temperature adjacent to the exciton guide.

17. The method of claim 14 further comprises creating the mechanical strain by applying an AC voltage to the exciton guide, where the exciton guide is a piezoelectric material.

18. The method of claim 14 wherein the ridge has a unidirectional grade from one end to the other end, thereby creating the mechanical strain along the ridge of the exciton guide.

19. The method of claim 14 further comprises generating an exciton along the ridge by projecting light onto the excitonic material.
